(19) United States
(12) Patent Application Publication
(10) Pub. No.: US 2025/0072197 A1
(43) Pub. Date: Feb. 27, 2025

(54) RESONANT CAVITY LIGHT-EMITTING DIODE AND PREPARING METHOD THEREOF, LIGHT-EMITTING ARRAY STRUCTURE

(71) Applicant: ENKRIS SEMICONDUCTOR, INC., Suzhou (CN)

(72) Inventor: Kai CHENG, Suzhou (CN)

(73) Assignee: ENKRIS SEMICONDUCTOR, INC., Suzhou (CN)

(21) Appl. No.: 18/797,090

(22) Filed: Aug. 7, 2024

(30) Foreign Application Priority Data
Aug. 23, 2023 (CN) 202311068408.8

(51) Int. Cl. H01L 33/46; H01L 27/15; H01L 33/24

(52) U.S. Cl. CPC H01L 33/465; H01L 27/15; H01L 33/24; H01L 2933/0025

(57) ABSTRACT

A resonant cavity light-emitting diodes includes a first reflective layer, a first type semiconductor layer, an active layer and a second type semiconductor layer sequentially which are stacked on a first substrate, and a second reflective layer covering a first sidewall of the second type semiconductor layer. An upper surface on a side of the second type semiconductor layer away from the first substrate serves as a light outlet. The first reflective layer and the second reflective layer form a resonant cavity. Light is capable to be reflected for many times in the resonant cavity. The first sidewall includes a lower tangency point and an upper tangency point which are arranged from bottom to top, and a tangent slope at the upper tangency point is larger than a tangent slope at the lower tangency point.

### CROSS-REFERENCE TO RELATED APPLICATIONS

The present application claims priority to Chinese Patent Application No. 202311068408.8, filed on Aug. 23, 2023, which is hereby incorporated by reference in its entirety.

### TECHNICAL FIELD

The present disclosure relates to the field of semiconductor technologies, and in particular, to a resonant cavity light-emitting diode and preparing method thereof, and a light-emitting array structure.

### BACKGROUND

With development of big data and a fifth-generation mobile communication technology, information processing of an optical network is continuously increased, and high-density broadband communication is continuously improved. As laser light sources, a Resonant Cavity Light-Emitting Diode (RCLED) and a Vertical Cavity Surface Emitting Laser (VCSEL) are increasingly concerned by people.

In the laser light source, an oxide layer having an opening is commonly used for lateral control of an electron and a photon. However, due to high complexity and poor stability of oxidation process, it is difficult to accurately control an oxidation depth. Moreover, there is a difference in thermal expansion coefficients between an oxide and a semiconductor, so that stress is generated at the opening of the oxide layer, thereby reliability of a device is reduced and thus high efficiency of light extraction is difficult to be ensured.

### SUMMARY

In view of this, embodiments of the present disclosure provide a resonant cavity light-emitting diode and preparing method thereof, and a light-emitting array structure, to solve the technical problem of low efficiency of light extraction in existing technologies.

According to a first aspect of the present disclosure an embodiment of the present disclosure provides a resonant cavity light-emitting diode, including: a first reflective layer, a first type semiconductor layer, an active layer and a second type semiconductor layer which are sequentially stacked on a first substrate, where the second type semiconductor layer includes a first sidewall and an upper surface located on a side of the first sidewall away from the first substrate; a second reflective layer covering at least the first sidewall; where the upper surface serves as a light outlet; and the first sidewall includes a lower tangency point and an upper tangency point arranged along a first direction, the first direction is a direction from the first substrate towards the second type semiconductor layer, and a tangent slope at the upper tangency point is larger than a tangent slope at the lower tangency point.

According to a second aspect of the present disclosure, an embodiment of the present disclosure provides a light-emitting array structure, including: a first light-emitting region and a second light-emitting region which are adjacent to each other, where the first light-emitting region includes the resonant cavity light-emitting diode described in the first aspect; and a pixel structure of the second light-emitting region includes any one of a light-emitting diode (LED) pixel structure, an organic light emitting diode (OLED) pixel structure, and a liquid crystal display (LCD) pixel structure.

According to a third aspect of the present disclosure, an embodiment of the present disclosure provides a method for preparing a resonant cavity light-emitting diode, including: preparing a mask layer on a growth substrate; etching the mask layer to form a through hole exposing the growth substrate, the mask layer forms a sidewall of the through hole, where the sidewall of the through hole includes a first tangency point and a second tangency point located on a side of the first tangency point away from the growth substrate, and a tangent slope at the first tangency point is larger than a tangent slope at the second tangency point; epitaxially preparing a second type semiconductor layer from the through hole, where a shape of a first sidewall of the second type semiconductor layer is matched with a shape of the sidewall of the through hole, the first sidewall includes an upper tangency point corresponding to the first tangency point and a lower tangency point corresponding to the second tangency point, and a tangent slope at the upper tangency point is larger than a tangent slope at the lower tangency point; preparing an active layer, a first type semiconductor layer and a first reflective layer on the second type semiconductor layer; inverting the foregoing structure onto a first substrate; removing the growth substrate and the mask layer; and preparing a second reflective layer on the first sidewall.

### BRIEF DESCRIPTION OF THE DRAWINGS

FIG. 1 is a structural schematic diagram of a resonant cavity light-emitting diode according to an embodiment of the present disclosure.

FIG. 2 is a structural schematic diagram of another resonant cavity light-emitting diode according to an embodiment of the present disclosure.

FIG. 3 is a structural schematic diagram of another resonant cavity light-emitting diode according to an embodiment of the present disclosure.

FIG. 4 is a structural schematic diagram of another resonant cavity light-emitting diode according to an embodiment of the present disclosure.

FIG. 5 is a structural schematic diagram of another resonant cavity light-emitting diode according to an embodiment of the present disclosure.

FIG. 6 is a top view of the resonant cavity light-emitting diode provided in FIG. 5.

FIG. 7 is a structural schematic diagram of another resonant cavity light-emitting diode according to an embodiment of the present disclosure.

FIG. 8 is a structural schematic diagram of another resonant cavity light-emitting diode according to an embodiment of the present disclosure.

FIG. 9 is an arrangement diagram of a resonant cavity light-emitting diode according to an embodiment of the present disclosure.

FIG. 10 is an arrangement diagram of another resonant cavity light-emitting diode according to an embodiment of t the present disclosure.

FIG. 11 is an arrangement diagram of another resonant cavity light-emitting diode according to an embodiment of the present disclosure.

FIG. 12 is a structural schematic diagram of a light-emitting array structure according to an embodiment of the present disclosure.

FIG. 13 is a structural schematic diagram of another light-emitting array structure according to an embodiment of the present disclosure.

FIG. 14 is a structural schematic diagram of another light-emitting array structure according to an embodiment of the present disclosure.

FIG. 15 is a flow diagram of a method for preparing a resonant cavity light-emitting diode according to an embodiment of the present disclosure.

FIG. 16 is a schematic diagram of an intermediate structure for preparing a resonant cavity light-emitting diode according to an embodiment of the present disclosure.

FIG. 17 is a schematic diagram of another intermediate structure for preparing a resonant cavity light-emitting diode according to an embodiment of the present disclosure.

FIG. 18 is a schematic diagram of another intermediate structure for preparing a resonant cavity light-emitting diode according to an embodiment of the present disclosure.

FIG. 19 is a schematic diagram of another intermediate structure for preparing a resonant cavity light-emitting diode according to an embodiment of the present disclosure.

FIG. 20 is a schematic diagram of another intermediate structure for preparing a resonant cavity light-emitting diode according to an embodiment of the present disclosure.

FIG. 21 is a schematic diagram of another intermediate structure for preparing a resonant cavity light-emitting diode according to an embodiment of the present disclosure.

FIG. 22 is a schematic diagram of another intermediate structure for preparing a resonant cavity light-emitting diode according to an embodiment of the present disclosure.

### DETAILED DESCRIPTION OF THE EMBODIMENTS

Hereinafter, technical solutions in embodiments of the present disclosure will be clearly and completely described below with reference to the drawings in the embodiments of the present disclosure. Obviously, the described embodiments are merely a portion of the embodiments of the present disclosure, but not all of the embodiments. Based on the embodiments of the present disclosure, all other embodiments obtained by a person with ordinary skill in the art without creative work belong to the protection scope of the present disclosure.

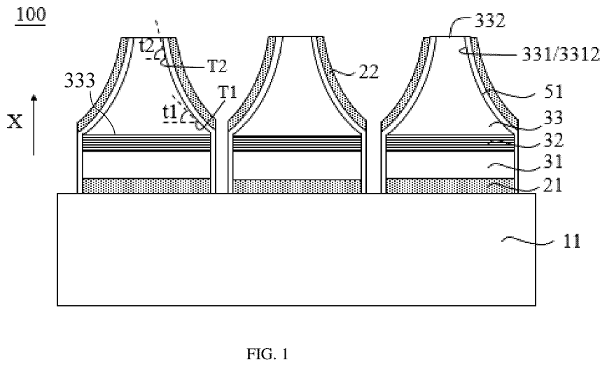

To improve efficiency of light extraction, FIG. 1 is a structural schematic diagram of a resonant cavity light-emitting diode according to an embodiment of the present disclosure. As shown in FIG. 1, the present disclosure provides a resonant cavity light-emitting diode 100 which includes: a first reflective layer 21, a first type semiconductor layer 31, an active layer 32 and a second type semiconductor layer 33 which are sequentially stacked on a first substrate 11, where the second type semiconductor layer 33 includes a first sidewall 331 and an upper surface 332 located on a side of the first sidewall 331 away from the first substrate 11; and a second reflective layer 22 which covers at least the first sidewall 331. The upper surface 332 serves as a light outlet. The first sidewall 331 includes a lower tangency point T1 and an upper tangency point T2 arranged along a first direction X, where the first direction X is a direction from the first substrate 11 towards the second type semiconductor layer 33, and a tangent slope t2 at the upper tangency point T2 is larger than a tangent slope t1 at the lower tangency point T1.

Specifically, the first type semiconductor layer 31, the active layer 32 and the second type semiconductor layer 33 are located between the first reflective layer 21 and the second reflective layer 22. The first reflective layer 21 and the second reflective layer 22 form a resonant cavity of the resonant cavity light-emitting diode. Light generated by the active layer 32 is reflected in the resonant cavity for many times, to make the light have a narrower wavelength peak, and thus spectral purity is improved. Furthermore, the tangent slope t2 at the upper tangency point T2 is larger than the tangent slope t1 at the lower tangency point T1, That is, the closer a tangent point to the light outlet, the larger the tangent slope of the first sidewall 311, and the smaller an included angle between the first sidewall 311 and a vertical direction, so that the light reflected for many times is easy to be reflected after reaching the first sidewall 311 at the light outlet, and is directionally emitted from the light outlet, which is capable to accelerates escape of a photon from the light outlet, and thus efficiency of light extraction is improved.

It should be noted that, taking the upper tangency point T2 as an example, the tangent slope t2 refers to a tangent value of an included angle between a tangent line of the first sidewall at the upper tangency point T2 and a plane where the first substrate 11 is located. That is, a tangent slope of a tangent point on the first sidewall 331 refers to a tangent value of an included angle between a tangent line of the first sidewall 331 at this tangent point and the plane where the first substrate 11 is located.

It should be noted that, FIG. 1 merely shows a cross-sectional view of three resonant cavity light-emitting diode units.

Optionally, when the first type semiconductor layer 31 and the second type semiconductor layer 33 are GaN-based material, the active layer 32 includes a combination of any two of GaN, InGaN, AlGaN and AlInGaN.

Optionally, when the first type semiconductor layer 31 and the second type semiconductor layer 33 are GaAs-based material, the active layer 32 includes a combination of any two of GaAs, InGaAs, AlGaAs and AlInGaAs.

Optionally, when the first type semiconductor layer 31 and the second type semiconductor layer 33 are GaP-based material, the active layer 32 includes a combination of any two of GaP, InGaP, AlGaP and AlInGaP.

In one embodiment, as shown in FIG. 1, along the first direction X, a tangent slope of the first sidewall 331 is gradually increased. Specifically, a contour of the first sidewall 331 is presented as a curve which is concave towards the second type semiconductor layer 33, such that the closer to the light outlet, the larger a tangent value of a tangency point of the first sidewall 331.

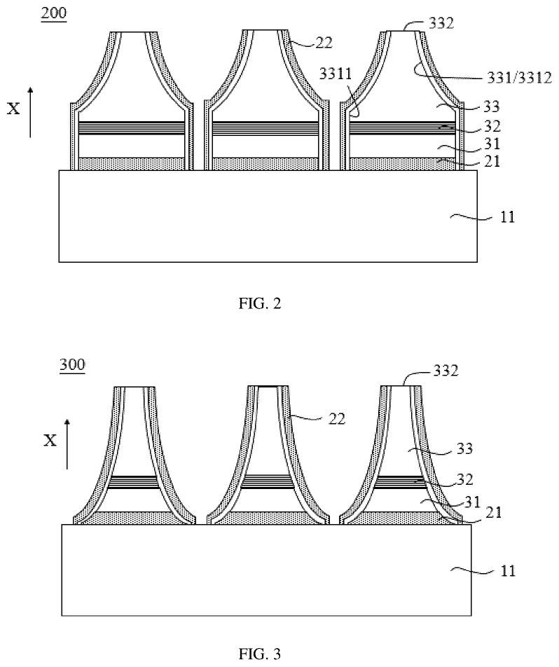

In one embodiment, FIG. 2 is a structural schematic diagram of another resonant cavity light-emitting diode according to an embodiment of the present disclosure. As shown in FIG. 2, the first sidewall 331 includes a first portion 3311 and a second portion 3312 located on a side of the first portion 3311 away from the first substrate 11, and the first portion 3311 is perpendicular to the first substrate 11. Along the first direction X, a tangent slope of the second portion 3312 is gradually increased. Specifically, a contour of the second portion 3312 is presented as a curve which is concave towards the second type semiconductor layer 33, such that the closer to the light outlet, the larger a tangent value of a tangency point of the first sidewall 331. It should be noted that, in a preparing process, the second type semiconductor layer 33 is first epitaxially prepared. After the epitaxy of the second type semiconductor layer 33 appears a relatively flat film layer with a constant area (a region where the first portion 3311 is located), then epitaxy of film layers of other semiconductor material is performed, such as the active layer 32 and the first type semiconductor layer 31, so that crystal quality of the film layers of other semiconductor material is improved, and thus a optoelectronic property of the resonant cavity light-emitting diode 200 is improved.

In one embodiment, FIG. 3 is a structural schematic diagram of another resonant cavity light-emitting diode according to an embodiment of the present disclosure. As shown in FIG. 3, along the first direction X, tangent slopes of sidewalls of the first type semiconductor layer 31, the active layer 32 and the second type semiconductor layer 33 are gradually increased. Specifically, contours of the sidewalls of the first type semiconductor layer 31, the active layer 32 and the second type semiconductor layer 33 are integrally presented as a curve which is concave towards the first substrate 11, such that the closer to the light outlet, the larger a tangent value of a tangency point on the sidewall. It should be noted that, in the resonant cavity light-emitting diode 300, along the first direction X, the first type semiconductor layer 31, the active layer 32 and the second type semiconductor layer 33 are integrally presented as a trend of gradually converging, to make light is more likely to be emitted upwards and towards the light outlet after being reflected on the sidewall, so that escape of a photon from the light outlet is accelerated, and the efficiency of light extraction is improved.

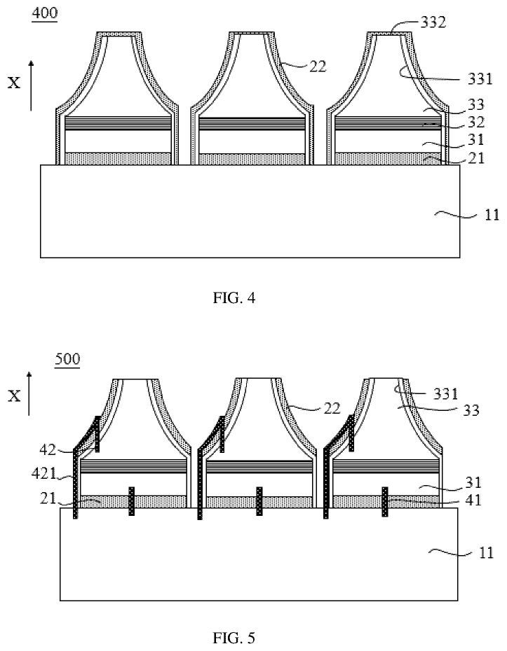

In one embodiment, FIG. 4 is a structural schematic diagram of another resonant cavity light-emitting diode according to an embodiment of the present disclosure. As shown in FIG. 4, in a resonant cavity light-emitting diode 400, the second reflective layer 22 also covers the upper surface 332 of the second type semiconductor layer 33, a sidewall of the first type semiconductor layer 31 and a sidewall of the active layer 32. Specifically, the second reflective layer 22 and the first reflective layer 21 form a resonant cavity nearly enclosed completely, to reduce leakage of light from the sidewalls of the first type semiconductor layer 31 and the active layer 32, so that reflection times of the light in the resonant cavity is increased, and thus a resonance effect of the light is improved, resulting in a narrower wavelength peak of the light, and thus the spectral purity is improved.

In one embodiment, as shown in FIG. 4, reflectivity of the second reflective layer 22 located on the first sidewall 331 is higher than reflectivity of the second reflective layer 22 located on the upper surface 332. Specifically, the upper surface 332 with lower reflectivity serves as the light outlet, and light is reflected in the resonant cavity formed by the first reflective layer 21 and the second reflective layer 22 for many times, and finally emitted from the upper surface 332.

In one embodiment, as shown in FIG. 1, the second type semiconductor layer 33 also includes a lower surface 333 close to the first substrate 11, and an area of the upper surface 332 of the second type semiconductor layer 33 is 0.05 to 0.5 times of an area of the lower surface 333. Specifically, the area of the upper surface 332 is an area of the light outlet, the area of the lower surface 333 is close to a projection area of the resonant cavity on the first substrate 11, the area of the light outlet is as small as possible, which may improve directionality and collimation of emission of the light. The projection area of the resonant cavity is as large as possible, that is, an area of the active layer 32 is as large as possible, which may increase the number of the photons and improve efficiency of internal quantum, and after the light is reflected in the resonant cavity for many times, the efficiency of the light extraction is improved. Optionally, the area of the upper surface 332 may be 0.1 times, 0.2 times, 0.3 times, or 0.4 times of the area of the lower surface 333.

In one embodiment, the first type semiconductor layer 31 is P-type doped, and the second type semiconductor layer 33 is N-type doped.

In one embodiment, FIG. 5 is a structural schematic diagram of another resonant cavity light-emitting diode according to an embodiment of the present disclosure. As shown in FIG. 5, a resonant cavity light-emitting diode 500 also includes a driving circuit located on the first substrate 11; a first electrode 41 located between the first type semiconductor layer 31 and the first substrate 11, which is configured to be electrically connected with the first type semiconductor layer the driving circuit; and a second electrode 42 located on the first sidewall 331, where an end of the second electrode 42 is electrically connected to the second type semiconductor layer 33, and another end of the second electrode 42 is electrically connected to the driving circuit through an electrode line 421.

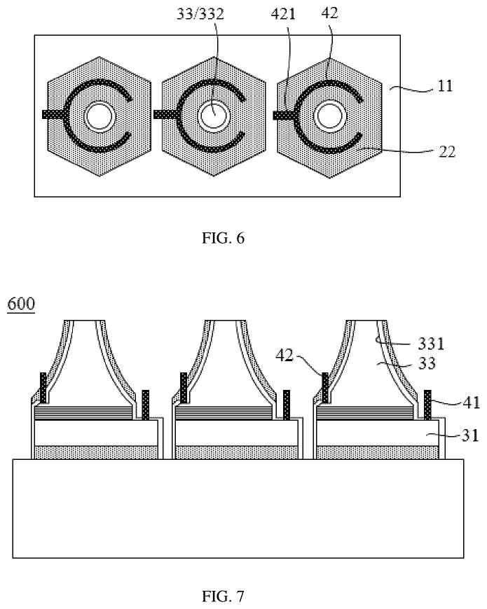

Optionally, FIG. 6 is a top view of the resonant cavity light-emitting diode provided in FIG. 5. As shown in FIG. 6, to reduce contact resistance between the second electrode 42 and the second type semiconductor layer 33, the second electrode 42 is an arc shape with a radian exceeding 180 degrees. The second electrode 42 is then electrically connected to the driving circuit on the first substrate 11 through the electrode line 421. It should be noted that, an outer contour of the second reflective layer 22 shown in FIG. 6 is hexagonal, that is, a shape of a projection of the second type semiconductor layer 33 on the first substrate 11 is hexagonal. Optionally, the shape of the projection of the second type semiconductor layer 33 on the first substrate 11 may be circular, polygonal, or other shapes. It should be noted that, a shape of a projection of the light outlet on the first substrate 11 shown in FIG. 6 is circular. Optionally, the shape of the projection of the light outlet is hexagonal, polygonal, or other shapes.

Optionally, the material of the first reflective layer 21 is pure metal or alloy with highly reflectivity, such as Al, Ag, Au and their alloys, and the like. An end of the first electrode 41 close to the first type semiconductor layer 31 may be prepared on the first reflective layer 21, to achieve electrical connection between the first type semiconductor layer 31 and the driving circuit. Optionally, the material of the first reflective layer 21 is a distributed Bragg reflector formed by an oxide material pair such as TiO₂/SiO₂, Ti₃O₅/SiO₂, Ta₂O₅/SiO₂, Ti₃O₅/Al₂O₃, ZrO₂/SiO₂, or TiO₂/Al₂O₃, or the like. and an end of the first electrode 41 is required to be in direct contact with the first type semiconductor layer 31 to achieve the electrical connection between the first type semiconductor layer and the driving circuit. Optionally, the material of the second reflective layer 22 is selected from the aforementioned pure metal or alloy with high reflectivity, or the distributed Bragg reflectors formed by the oxide material pair, and the like.

Optionally, the first electrode 41 is an interconnected common electrode, and the second electrode 42 is an independent electrode separately providing an electrical signal for each resonant cavity light-emitting diode unit; or, the second electrode 42 is an interconnected common electrode, and the first electrode 41 is an independent electrode.

It should be noted that, FIG. 5 does not show the driving circuit. The first substrate 11 may be a driving circuit board. The first substrate 11 includes a driving circuit which provides a driving signal for the resonant cavity light-emitting diode 500.

Optionally, as shown in FIG. 1, a passivation layer 51 is formed on sidewalls of the first type semiconductor layer 31, the active layer 32, the second type semiconductor layer 33 and the first reflective layer 32. The material of the passivation layer 51 may be SiO₂, Al₂O₃, SiN, polyimide, photoresist, or other photo patternable polymers, and the like. The second electrode 42 is electrically connected with the second type semiconductor layer 33 through a via hole in the passivation layer.

In one embodiment, FIG. 7 is a structural schematic diagram of another resonant cavity light-emitting diode according to an embodiment of the present disclosure. As shown in FIG. 7, in a resonant cavity light-emitting diode 600, the first electrode 41 is located on a mesa surface of the first type semiconductor layer 31, and the second electrode 42 is located on the first sidewall 331 of the second type semiconductor layer 33.

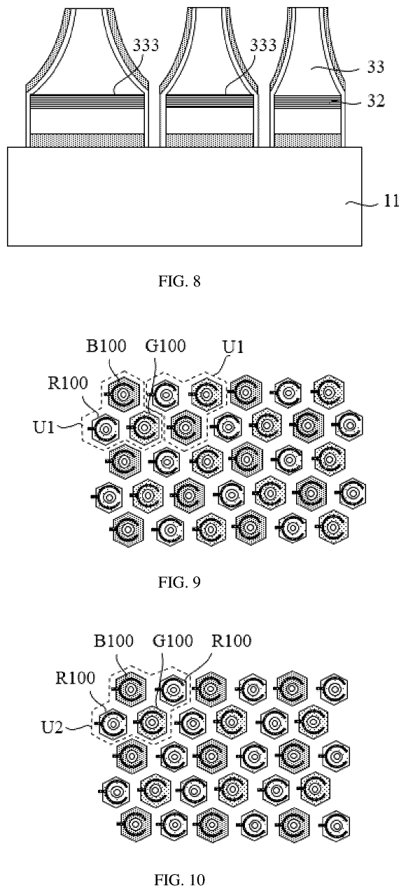

In one embodiment, FIG. 8 is a structural schematic diagram of another resonant cavity light-emitting diode according to an embodiment of the present disclosure. As shown in FIG. 8, the second type semiconductor layer 33 includes a lower surface 333 close to the active layer 32 (that is, a lower surface 333 close to the first substrate), and there are at least two the resonant cavity light-emitting diodes having different areas of the lower surfaces 333 of the second type semiconductor layers 3, to make light-emitting wavelengths of the two resonant cavity light-emitting diodes be different. It should be noted that, taking the material of the active layer 32 as InGaN/GaN as an example, the areas of the lower surface 333 of the two resonant cavity light-emitting diodes are different, and areas of the subsequently epitaxial active layer 32 are different. Due to different doping rates of an In component in the active layers with different areas, the light-emitting wavelengths of the two prepared resonant cavity light-emitting diodes finally are different. Optionally, the larger the area of the lower surface 333, the shorter the emission wavelength of the resonant cavity light-emitting diode.

In one embodiment, FIG. 9 is an arrangement diagram of a resonant cavity light-emitting diode according to an embodiment of the present disclosure. As shown in FIG. 9, the resonant cavity light-emitting diodes R100, G100 and B100 emit red light, green light and blue light, respectively. Each pixel unit U1 includes one R100, one G100 and one B100, and forms a delta layout. Optionally, the resonant cavity light-emitting diode may also be also be configured to include any of a standard RGB arrangement or a diamond type arrangement.

Optionally, considering that luminous efficiency of red light is lower compared to luminous efficiency of green light or blue light, a pixel unit may include a plurality of resonant cavity light-emitting diodes that emit red light, to balance ratios of three colors in a pixel unit. FIG. 10 is an arrangement diagram of another resonant cavity light-emitting diode according to an embodiment of the present disclosure. FIG. 11 is an arrangement diagram of another resonant cavity light-emitting diode according to an embodiment of the present disclosure. As shown in FIG. 10 and FIG. 11, the resonant cavity light-emitting diodes R100, G100 and B100 emit red light, green light and blue light, respectively. Each pixel unit U2 includes two R100, one G100 and one B100. Among them, as shown in FIG. 10, in the pixel unit U2, two R100, one G100 and one B100 are in staggered arrangement. As shown in FIG. 11, in the pixel unit U2, two R100, one G100, and one B100 are in standard RGB arrangement.

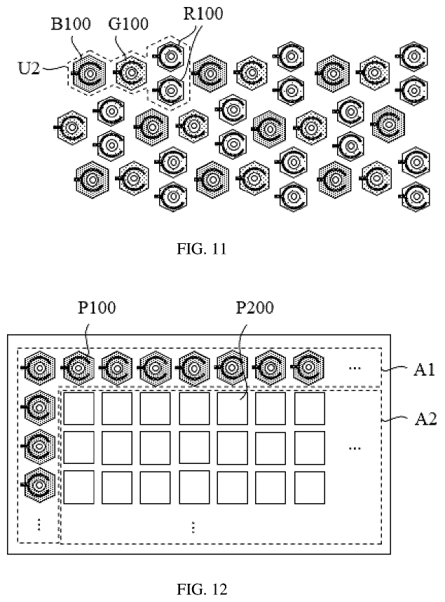

Based on a same inventive concept, embodiments of the present disclosure also provide a light-emitting array structure. FIG. 12 is a structural schematic diagram of a light-emitting array structure according to an embodiment of the present disclosure. As shown in FIG. 12, the present disclosure further provides a light-emitting array structure which includes a first light-emitting region A1 and a second light-emitting region A2 adjacent to each other. The first light-emitting region A1 includes the resonant cavity light-emitting diode P100 described in any of the foregoing embodiments. A pixel structure P200 of the second light-emitting region A2 includes any one of an LED pixel structure, an OLED pixel structure, and an LCD pixel structure.

Compared to the LED pixel structure, the OLED pixel structure and the LCD pixel structure, the resonant cavity light-emitting diode disclosed in the present disclosure is capable to improve the efficiency of the light extraction, and improve brightness and chromaticity. Optionally, in traditional light-emitting array structures, there exists a problem of lower brightness in a bezel region. In the light-emitting array structure provided by the present disclosure, the first light-emitting region may be arranged in the bezel region, and the second light-emitting region may be arranged in the central region, to improve uniformity of the brightness of the light-emitting array structure.

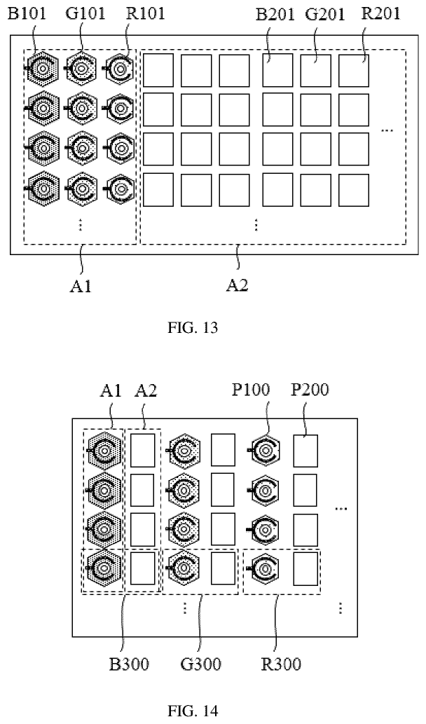

Optionally, FIG. 13 is a structural schematic diagram of another light-emitting array structure according to an embodiment of the present disclosure. As shown in FIG. 13, the first light-emitting region A1 includes resonant cavity light-emitting diodes B101, G101 and R101 which emit blue light, green light and red light, respectively. The second light-emitting region A2 includes pixel structures B201, G201 and R201 emitting blue light, green light and red light, respectively. A color arrangement of the resonant cavity light-emitting diodes is the same as a color arrangement of the pixel structures, and belongs to the standard RGB arrangement.

Optionally, FIG. 14 is a structural schematic diagram of another light-emitting array structure according to an embodiment of the present disclosure. As shown in FIG. 14, the first light-emitting region A1 and the second light-emitting region A2 are alternately arranged in a row direction. A side of each pixel structure P200 is provided with one resonant cavity light-emitting diode P100, to improve the problem of lower brightness of the pixel structure P200. Optionally, as shown in FIG. 14, a blue sub-pixel B300 includes one resonant cavity light-emitting diode P100 emitting blue light and one pixel structure P200 emitting blue light. A green sub-pixel G300 includes one resonant cavity light-emitting diode P100 emitting green light and one pixel structure P200 emitting green light. A red sub-pixel R300 includes one resonant cavity light-emitting diode P100 emitting red light and one pixel structure P200 emitting red light.

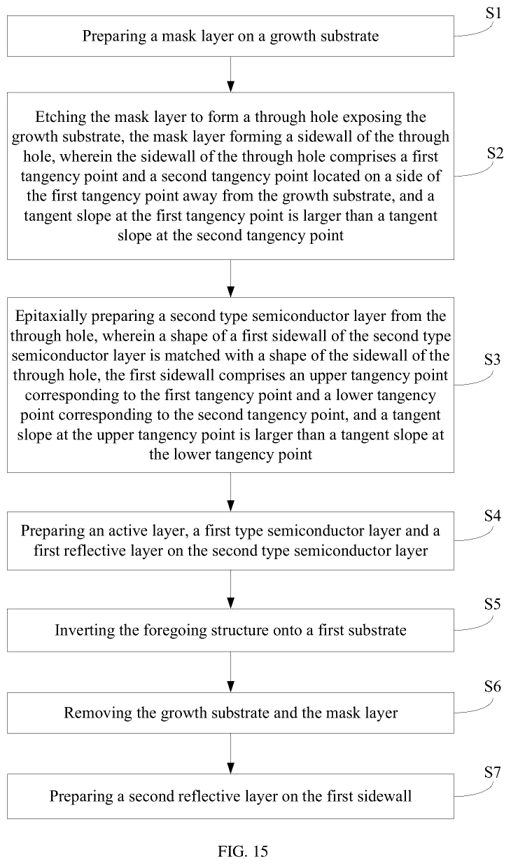

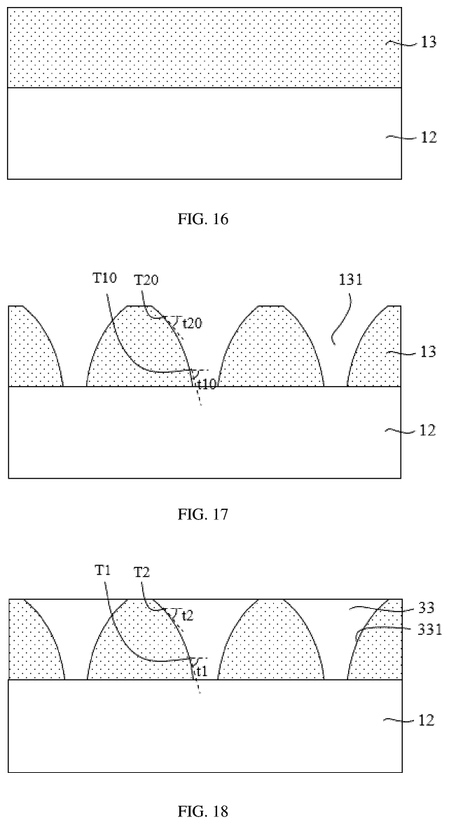

FIG. 15 is a flow diagram of a method for preparing a resonant cavity light-emitting diode according to an embodiment of the present disclosure. FIGS. 16 to 22 are schematic diagrams of intermediate structures for preparing a resonant cavity light-emitting diode according to an embodiment of the present disclosure. As shown in FIG. 15, the present disclosure also provides a method for preparing a resonant cavity light-emitting diode, which includes the following steps.

Step S1: As shown in FIG. 16, forming a mask layer 13 on a growth substrate 12.

Optionally, the growth substrate 12 includes any one of sapphire, silicon, carborundum, silicon germanium or GaN.

Step S2: As shown in FIG. 17, etching the mask layer 13 to form a through hole 131 exposing the growth substrate 12. The mask layer 13 forms a sidewall of the through hole 131. The sidewall of the through hole 131 includes a first tangency point T10 and a second tangency point T20 located on a side of the first tangency point T10 away from the growth substrate 12. A tangent slope t10 at the first tangency point T10 is larger than a tangent slope t20 at the second tangency point T20.

Optionally, the mask layer 13 is etched by photolithography to form the sidewall of the through-hole 131 with different tangent line slopes.

Step S3: As shown in FIG. 18, epitaxially preparing a second type semiconductor layer 33 from the through hole 131. A shape of a first sidewall 331 of the second type semiconductor layer 33 is matched with a shape of the sidewall of the through hole 131. The first sidewall 331 includes an upper tangency point T1 corresponding to the first tangency point T10 and a lower tangency point T2 corresponding to the second tangency point T20, and a tangent slope t1 at the upper tangency point T1 is larger than a tangent slope t2 at the lower tangency point T2.

Optionally, before preparing the second type semiconductor layer 33, a nucleating layer and a buffer layer are epitaxially prepared at the bottom of the through hole 131. When the second type semiconductor layer 33 is GaN-based material, the material of the nucleation layer is AlN, and the material of the buffer layer is GaN.

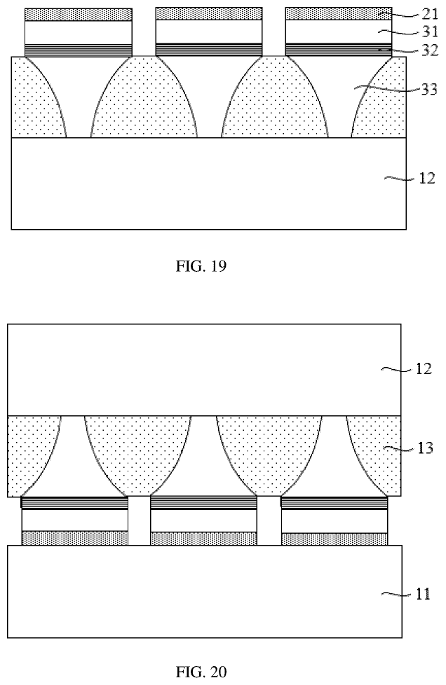

Step S4: As shown in FIG. 19, preparing an active layer 32, a first type semiconductor layer 31 and a first reflective layer 21 on the second type semiconductor layer 33.

Optionally, when the second type semiconductor layer 33 is GaN-based material, the active layer 32 includes a combination of any two of GaN, InGaN, AlGaN and AlInGaN.

Step S5: As shown in FIG. 20, inverting the foregoing structure onto a first substrate 11.

Optionally, the first substrate 11 is a driving circuit board. Optionally, before the step S5, preparing a first electrode which is electrically connected to the first type semiconductor layer 31. In step S5, the first electrode is electrically connected to the driving circuit board (the first substrate 11).

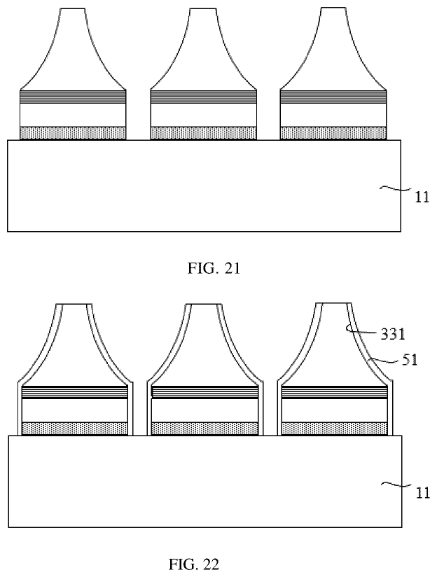

Step S6: As shown in FIG. 21, removing the growth substrate 12 and the mask layer 13.

Optionally, a removal method for the growth substrate 12 is laser lift-off. Optionally, a removal method for the mask layer 13 is etching.

Optionally, as shown in FIG. 22, after the step S6, preparing a passivation layer 51 covering sidewalls of the first type semiconductor layer 31, the active layer 32 and the second type semiconductor layer 33. Optionally, the passivation layer 51 may cover an upper surface on a side of the second type semiconductor layer 33 away from the first substrate 11.

Step S7: As shown in FIG. 1, preparing a second reflective layer 22 on the first sidewall 331. Optionally, the second reflective layer 22 may be prepared on the passivation layer 51.

It should be noted that, the second type semiconductor layer 33 is first epitaxially grown on the growth substrate 12 in a smaller area, and is laterally grown epitaxially to fill the through-hole 131. Taking GaN as the material of the second type semiconductor layer 33 as an example, dislocation in GaN is mainly line dislocation with crystal orientation, that is, the line dislocation extends along a thickness direction of the growth substrate 12. In this point, the smaller the epitaxial growth area of the second type semiconductor layer 33, the lower the density of the dislocation in GaN, so that crystal quality of the second type semiconductor layer 33 is improved. Moreover, the mask layer 13 is patterned by photolithography to form the through hole 131 with a specific shape, to obtain the resonant cavity light-emitting diode with a specific shape, and the process is relatively simple.

The resonant cavity light-emitting diode prepared by the method provided in the present embodiment includes: the first reflective layer, the first type semiconductor layer, the active layer and the second type semiconductor layer which are sequentially stacked on the first substrate. The second reflective layer covers the first sidewall of the second type semiconductor layer. The upper surface on the side of the second type semiconductor layer away from the first substrate serves as a light outlet. The first reflective layer and the second reflective layer form a resonant cavity of the resonant cavity light-emitting diode, so that light is capable to be reflected for many times in the resonant cavity. The first sidewall includes the lower tangency point and the upper tangency point which are arranged from bottom to top, and a tangent slope at the upper tangency point is larger than a tangent slope at the lower tangency point, that is, the closer to the light outlet, the larger the tangent slope of a tangency point, and the smaller the included angle between the first sidewall and a vertical direction, so that the light reflected many times is easy to be reflected after reaching the first sidewall and is directionally emitted from the upper surface, and thus escape of a photon from the light outlet is accelerated, and then efficiency of light extraction is improved.

It should be understood that, the term “including” and its variants used in the present disclosure are open to include, that is, “including but not limited to”. The term “an embodiment” means “at least one embodiment”. The term “another embodiment” means “at least one other embodiment”. In the present specification, the illustrative expressions of the above-mentioned terms are not necessarily aimed at the same embodiment or example. Moreover, the described specific features, structures, material, or characteristics may be combined in any one or more embodiments or examples in a suitable manner. In addition, a person skilled in the art can incorporate and combine different embodiments or examples and features of different embodiments or examples described in the present specification without contradicting each other.

The above-mentioned embodiments are merely preferred embodiments of the present disclosure, and is not used to limit the present disclosure. Any modifications and equivalent replacements, and the like which are made within the spirit and principle of the present disclosure, should be included within the protection scope of the present disclosure.

What is claimed is:

1. A resonant cavity light-emitting diode, comprising:
a first reflective layer, a first type semiconductor layer, an active layer and a second type semiconductor layer which are sequentially stacked on a first substrate, wherein the second type semiconductor layer comprises a first sidewall and an upper surface located on a side of the first sidewall away from the first substrate;
a second reflective layer covering at least the first sidewall,
wherein the upper surface serves as a light outlet; and
the first sidewall comprises a lower tangency point and an upper tangency point arranged along a first direction, the first direction is a direction from the first substrate towards the second type semiconductor layer, and a tangent slope at the upper tangency point is larger than a tangent slope at the lower tangency point.

2. The resonant cavity light-emitting diode according to claim 1, wherein along the first direction, a tangent slope of the first sidewall is gradually increased.

3. The resonant cavity light-emitting diode according to claim 1, wherein the first sidewall comprises a first portion and a second portion located on a side of the first portion away from the first substrate;
the first portion is perpendicular to the first substrate; and
along the first direction, a tangent slope of the second portion is gradually increased.

4. The resonant cavity light-emitting diode according to claim 1, wherein along the first direction, tangent slopes of sidewalls of the first type semiconductor layer, the active layer and the second type semiconductor layer are gradually increased.

5. The resonant cavity light-emitting diode according to claim 1, wherein the second reflective layer further covers the upper surface of the second type semiconductor layer, a sidewall of the first type semiconductor layer and a sidewall of the active layer.

6. The resonant cavity light-emitting diode according to claim 5, wherein reflectivity of the second reflective layer located on the first sidewall is higher than reflectivity of the second reflective layer located on the upper surface.

7. The resonant cavity light-emitting diode according to claim 1, wherein the second type semiconductor layer further comprises a lower surface close to the first substrate, and an area of the upper surface of the second type semiconductor layer is 0.05 to 0.5 times of an area of the lower surface.

8. The resonant cavity light-emitting diode according to claim 1, wherein the first type semiconductor layer is P-type doped, and the second type semiconductor layer is N-type doped.

9. The resonant cavity light-emitting diode according to claim 1, wherein a material of the first reflective layer is pure metal or alloy.

10. The resonant cavity light-emitting diode according to claim 1, wherein a material of the first reflective layer is a distributed Bragg reflector formed by one of oxide material pairs in TiO₂/SiO₂, Ti₃O₅/SiO₂, Ta₂O₅/SiO₂, Ti₃O₅/Al₂O₃, ZrO₂/SiO₂ or TiO₂/Al₂O₃.

11. The resonant cavity light-emitting diode according to claim 1, wherein sidewalls of the first type semiconductor layer, the active layer, the second type semiconductor layer and the first reflective layer are provided with a passivation layer.

12. The resonant cavity light-emitting diode according to claim 1, wherein the resonant cavity light-emitting diode further comprises:
a driving circuit located on the first substrate;
a first electrode located between the first type semiconductor layer and the first substrate, configured to electrically connect the first type semiconductor layer and the driving circuit; and
a second electrode located on the first sidewall, wherein an end of the second electrode is electrically connected to the second type semiconductor layer, and another end of the second electrode is electrically connected to the driving circuit through an electrode line.

13. The resonant cavity light-emitting diode according to claim 12, wherein the second electrode is an arc shape having a radian exceeding 180 degrees.

14. The resonant cavity light-emitting diode according to claim 1, wherein the resonant cavity light-emitting diode further comprises:
a driving circuit located on the first substrate;
a first electrode located on a mesa surface of the first type semiconductor layer, configured to be electrically connected with the first type semiconductor layer and the driving circuit; and
a second electrode located on the first sidewall, wherein an end of the second electrode is electrically connected to the second type semiconductor layer, and another end of the second electrode is electrically connected to the driving circuit through an electrode wire.

15. The resonant cavity light-emitting diode according to claim 1, wherein the second type semiconductor layer comprises a lower surface close to the active layer, and
there are at least two the resonant cavity light-emitting diodes having different areas of the lower surface of the second type semiconductor layer, to make light-emitting wavelengths of the two resonant cavity light-emitting diodes be different.

16. A light-emitting array structure, comprising:
a first light-emitting region and a second light-emitting region which are adjacent to each other,
wherein the first light-emitting region comprises the resonant cavity light-emitting diode according to claim 1; and
a pixel structure of the second light-emitting region comprises any one of a light-emitting diode (LED) pixel structure, an organic light emitting diode (OLED) pixel structure, and a liquid crystal display (LCD) pixel structure.

17. The light-emitting array structure according to claim 16, wherein the first light-emitting region and the second light-emitting region are alternately arranged in a row direction.

18. The light-emitting array structure according to claim 16, wherein the light-emitting region is disposed in a bezel region.

19. The light-emitting array structure according to claim 16, wherein a pixel unit in the first light-emitting region comprises a plurality of resonant cavity light-emitting diodes emitting red light.

20. A method for preparing a resonant cavity light-emitting diode, comprising:
preparing a mask layer on a growth substrate;
etching the mask layer to form a through hole exposing the growth substrate, the mask layer forming a sidewall of the through hole, wherein the sidewall of the through hole comprises a first tangency point and a second tangency point located on a side of the first tangency point away from the growth substrate, and a tangent slope at the first tangency point is larger than a tangent slope at the second tangency point;
epitaxially preparing a second type semiconductor layer from the through hole, wherein a shape of a first sidewall of the second type semiconductor layer is matched with a shape of the sidewall of the through hole, the first sidewall comprises an upper tangency point corresponding to the first tangency point and a lower tangency point corresponding to the second tangency point, and a tangent slope at the upper tangency point is larger than a tangent slope at the lower tangency point;
preparing an active layer, a first type semiconductor layer and a first reflective layer on the second type semiconductor layer;
inverting the foregoing structure onto a first substrate;
removing the growth substrate and the mask layer; and
preparing a second reflective layer on the first sidewall.
